(19) United States
(12) Patent Application Publication
(10) Pub. No.: US 2012/0034452 A1
(43) Pub. Date: Feb. 9, 2012

(54) ARTICLE AND METHOD FOR MANUFACTURING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CHUANG MA, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/010,957

(22) Filed: Jan. 21, 2011

(30) Foreign Application Priority Data
Aug. 4, 2010 (CN) 201010245062.0

(51) Int. Cl. B32B 7/02; C23C 14/06; C23C 14/35

(52) U.S. Cl. 428/336; 428/332; 204/192.26

(57) ABSTRACT

An article includes a substrate and a color layer deposited on the substrate. The color layer has an L* value between about 36 to about 48, an a* value between about 4 to about 5, and a b* value between about 2 to about 4 in the CIE L*a*b* color space.

### CROSS-REFERENCE TO RELATED APPLICATIONS

The present application is related to co-pending U.S. patent applications (Attorney Docket No. US34923, US34942, US34943), entitled “ARTICLE AND METHOD FOR MANUFACTURING SAME”, by Zhang et al. These applications have the same assignee as the present application and have been concurrently filed herewith. The above-identified applications are incorporated herein by reference.

### BACKGROUND

1. Technical Field

The exemplary disclosure generally relates to articles and methods for manufacturing the articles.

2. Description of Related Art

Vacuum deposition is used to form a thin film or coating on housings of portable electronic devices, to improve abrasion resistance. However, typical vacuum deposition only can deposit black or gold coatings on the housing, limiting possible variations in appearance compared to other processes used, such as anodic treatment.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary embodiment of an article and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an exemplary embodiment of an article.

FIG. 2 is a schematic view of a magnetron sputtering coating machine for manufacturing the article in FIG. 1.

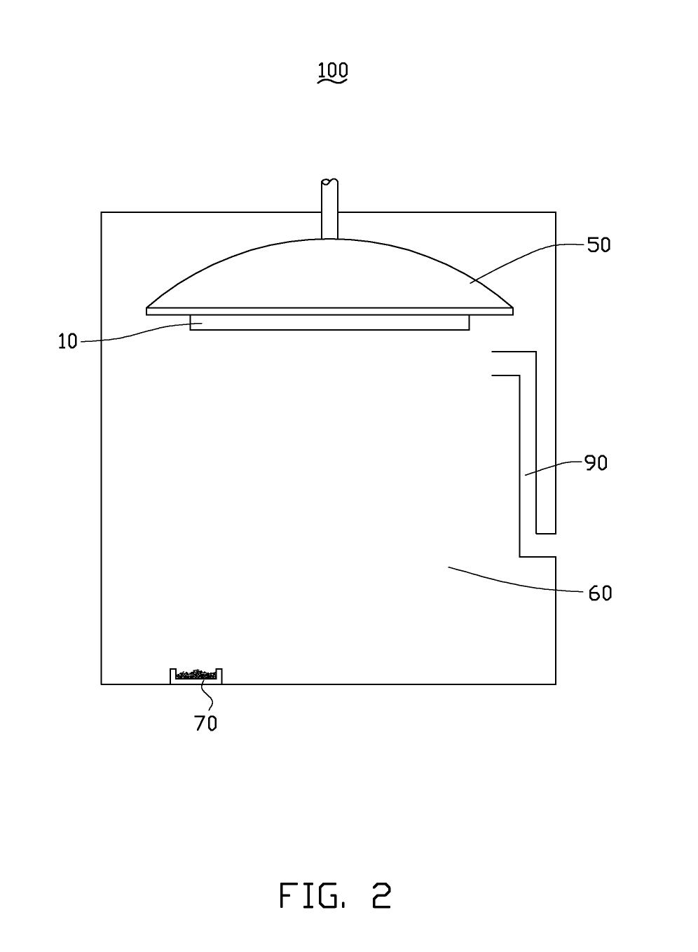

### DETAILED DESCRIPTION

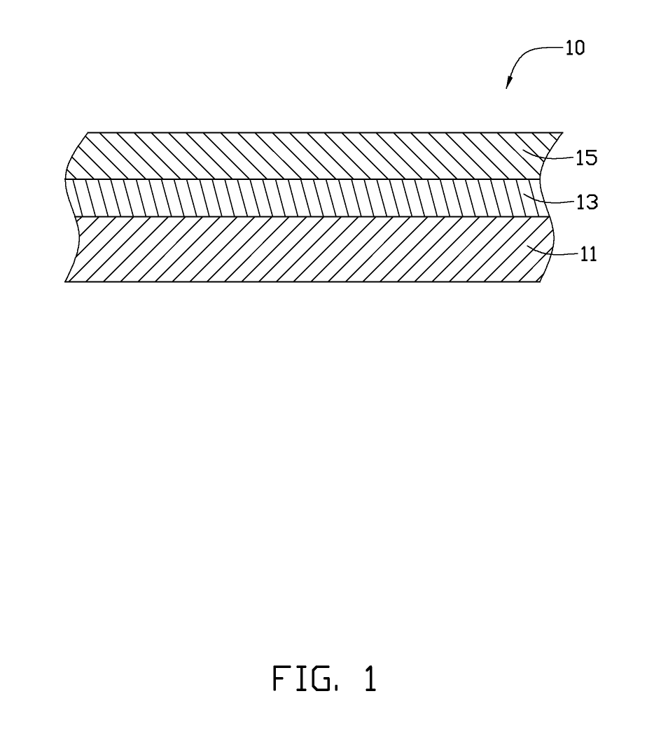

Referring to FIG. 1, an exemplary embodiment of an article 10 manufactured, by a coating process, such as by vacuum deposition, and includes a substrate 11, a bonding layer 13 deposited on the substrate 11, and a color layer 15 deposited on the bonding layer 13 opposite to the substrate 11. The article 10 may be a housing of an electronic device. The substrate 11 may be made of aluminum alloy, magnesium alloy, or stainless steel.

The bonding layer 13 is formed between the substrate 11 and the color layer 15 for improving the binding force between the substrate 11 and the color layer 15. The bonding layer 13 may be made of titanium. The bonding layer 13 has a thickness ranging from about 0.05 micrometers to about 0.2 micrometers, and in this exemplary embodiment has a thickness of about 0.1 micrometers. In this exemplary embodiment, the bonding layer 13 has a color that does not affect the color of the color layer 15, such as silver, white, or gray.

The color layer 15 is a titanium carbon-nitride layer. The color layer 15 has an L* value between about 36 to about 48, an a* value between about 4 to about 5, and a b* value between about 2 to about 4 in the CIE L*a*b* (CIE LAB) color space, so the color layer 15 is substantially chocolate color. The color layer 15 has a thickness ranging from about 0.5 micrometers to about 3 micrometers, and preferably has a thickness of 1 micrometers.

A method for manufacturing the article 10 manufactured by vacuum deposition may include at least the following steps.

A substrate 11 is provided. The substrate 11 may be made of aluminum alloy, magnesium alloy, or stainless steel.

The substrate 11 is pretreated. For example, the substrate 11 may be washed with a solution (e.g., alcohol or acetone) in an ultrasonic cleaner, to remove, e.g., grease, dirt, and/or impurities. The substrate 11 is then dried. The substrate 11 may also be cleaned using argon plasma cleaning. The substrate 11 is retained on a rotating bracket 50 in a vacuum chamber 60 of a magnetron sputtering coating machine 100. The vacuum level of the vacuum chamber 60 is adjusted to 8.0×10−3 Pa. Pure argon is fed into the vacuum chamber 60 at a flux of about 300 Standard Cubic Centimeters per Minute (sccm) to 600 sccm from a gas inlet 90. A bias voltage is applied to the substrate 11 in a range of −300 to −800 volts for about 5 to about 10 min. The substrate 11 may then be washed by argon plasma, to further remove any contaminants. Thus, the binding force between the substrate 11 and the color layer 15 is enhanced.

The bonding layer 13 is deposited on the substrate 11 by magnetron sputtering. The temperature in the vacuum chamber 60 is adjusted to be in range from 100 degrees Celsius (° C.) to 150° C., i.e., the reaction temperature is about 100° C. to about 150° C.; argon is fed into the vacuum chamber 60 at a flux from about 100 sccm to about 200 sccm from the gas inlet 90, i.e. the reaction gas for depositing the bonding layer 13 is argon. The substrate 11 is rotated in a range from 2 revolutions per minute (rpm) to 5 rpm. A titanium target 70 in the vacuum chamber 60 is evaporated at a power from about 8 kW to about 11 kW, and a bias voltage is applied to the substrate 11 is in a range from about −100 volts to about −200 volts and with a duty cycle ranging from about 30% to about 70%, for about 5 min to about 15 min, to deposit the bonding layer 13 on the substrate 11.

The color layer 15 is deposited on the bonding layer 13 by magnetron sputtering. The temperature in the vacuum chamber 60 is kept between about 100° C. to about 150° C., i.e., the reaction temperature is about 50° C. to about 180° C. Argon is continuously fed into the vacuum chamber 60 at a flux from about 100 sccm to about 200 sccm from the gas inlet 90. Nitrogen is fed into the vacuum at a flux from about 40 sccm to 80 sccm and ethylene is fed into the vacuum at a flux from about 5 sccm to 20 sccm from the gas inlet 90, i.e, the reaction gas for depositing the color layer 15 is ethylene and nitrogen. The substrate 11 is rotated in a range from about 2 rpm to about 5 rpm. The titanium target 70 is evaporated at a power from about 8 kW to about 11 kW. A bias voltage is applied to the substrate 11 is in a range of about −10 volts to about −250 volts and with a duty cycle ranging from about 10% to about 100%, for about 10 min to about 30 min, to deposit the color layer 15 on the bonding layer 13.

The color layer 15 has an L* value between about 36 to about 48, an a* value between about 4 to about 5, and a b* value between about 2 to about 4 in the CIE L*a*b* (CIE LAB) color space, and is substantially chocolate color.

To form the color layer 15 in the above exemplary embodiment, the titanium target 70 is employed, and by adjusting the flux of the reaction gas, i.e., adjusting the flux of ethylene and nitrogen, to change the composition of the color layer 15. So the color of the color layer 15 has an L* value between about 36 to about 48, an a* value between about 4 to about 5, and a b* value between about 2 to about 4 in the CIE L*a*b* (CIE LAB) color space, thereby a substantially chocolate colored article 10 is produced.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An article, comprising:
a substrate; and
a color layer deposited on the substrate, wherein the color layer has an L* value between about 36 to about 48, an a* value between about 4 to about 5, and a b* value between about 2 to about 4 in the CIE L*a*b* color space.

2. The article as claimed in claim 1, wherein the color layer is a titanium carbon-nitride layer.

3. The article as claimed in claim 1, wherein the color layer has a thickness ranging from about 0.5 micrometers to about 3 micrometers.

4. The article as claimed in claim 1, wherein the color layer has a thickness of 1 micrometers.

5. The article as claimed in claim 1, wherein the substrate is made of aluminum alloy, magnesium alloy, or stainless steel.

6. The article as claimed in claim 1, further comprising a bonding layer formed between the substrate and the color layer for improving the binding force between the substrate and the color layer.

7. The article as claimed in claim 6, wherein the bonding layer is made of titanium.

8. The article as claimed in claim 6, wherein the bonding layer has a thickness ranging from about 0.05 micrometers to about 0.2 micrometers.

9. The article as claimed in claim 6, wherein the bonding layer has a thickness of 0.1 micrometers.

10. A method for manufacturing a article comprising steps of:
providing a substrate; and
depositing a color layer on the substrate by magnetron sputtering, wherein the substrate is retained in a vacuum chamber, the temperature in the vacuum chamber is kept from about 100° C. to about 150° C., argon is fed into the vacuum chamber at a flux from about 100 sccm to about 200 sccm; nitrogen is fed into the vacuum at a flux from 40 sccm to 80 sccm and ethylene is fed into the vacuum at a flux from 5 sccm to 20 sccm, a titanium target in the vacuum chamber is evaporated at a power from about 8 kw to about 11 kw; a bias voltage is applied to the substrate is in a range of about −10 volts to about −250 volts and with a duty cycle ranging from about 10% to about 100%, for about 10 min to about 30 min, to deposit the color layer on the substrate.

11. The method of claim 10, wherein the color layer has an L* value between about 36 to about 48, an a* value between about 4 to about 5, and a b* value between about 2 to about 4 in the CIE L*a*b* color space

12. The method of claim 10, wherein the color layer is a titanium carbon-nitride layer.

13. The method of claim 10, wherein the substrate is made of aluminum alloy, magnesium alloy, or stainless steel.

14. The method of claim 10, further including a step of depositing a bonding layer on the substrate by magnetron sputtering before depositing the color layer on the substrate, wherein during depositing the bonding layer, the temperature in the vacuum chamber is adjusted in a range from 100° C. to 150° C., argon is fed into the vacuum chamber at a flux from about 100 sccm to about 200 sccm, the titanium target in the vacuum chamber is evaporated at a power from about 8 kW to about 11 kW; and a bias voltage is applied to the substrate in a range from about −100 volts to about −200 volts and with a duty cycle ranging from about 30% to about 70%, for about 5 min to about 15 min, to deposit the bonding layer on the substrate.
